(19) United States
(12) Patent Application Publication
(10) Pub. No.: US 2003/0121976 A1
(43) Pub. Date: Jul. 3, 2003

(54) Organic light sensors for use in a mobile communication device

(75) Inventor: Toni Ostergard, Turku (FI)

Correspondence Address: Ware, Fressola, Van Der Sluys & Adolphson, LLP, Building Five, Bradford Green, 755 Main Street, P.O. Box 224, Monroe, CT, 06468, US

(73) Assignee: Nokia Corporation

(21) Appl. No.: 10/040,308

(22) Filed: Jan. 3, 2002

(51) Int. Cl. G06K 7/10; G06K 7/14

(52) U.S. Cl. 235/454

(57) ABSTRACT

An organic light sensor for use in a mobile communication device includes at least one organic photodiode/photodetector for detecting the presence of illumination of a predetermined wavelength and for generating a light detection signal thereto. The sensor can have a stacked or planar geometry or a combination of both. The organic photodiode/photodetector is carried on an internal or external transparent or non-transparent substrate. An organic circuit couples the organic sensor to electronic circuitry in the mobile communication device. Examples of construction and applications including image scanning are presented.

### BACKGROUND OF THE INVENTION

The present invention relates generally to portable electronic devices and more particularly with mobile communication devices having intelligent light detection sensor systems. The present invention also relates to the manufacturing of such “light detectors” by using organic semiconductors as the active material(s), and the use of manufacturing techniques related to organic semiconductors for use in the sensor system of the mobile communication device.

The complexity of portable electronic devices such as mobile cellular telephone devices are expected to become more and more complex within the near future as consumers demand more sophisticated and advanced services and capabilities. These devices are evolving from simple mobile telephones to become more like personal digital assistants (PDA) devices. As a consequence of this evolution for more advanced features, the devices are manufactured with more “intelligence” and capabilities to determine the needed actions due to specific situations or environmental parameters. Simple examples of this are for example, the need for display lighting in dark dimly lit conditions versus daylight or lighted conditions. Another example is a louder alarm signal in traffic versus a silent signal in a library. Another example might be the need for a modified User Interface (UI) output, in any particular way, since the owner of the device is “in motion” (for example, the UI output signal might switch from visual to audible.)

In all the above examples, the sensors that are used to determine the “state” of the mobile communication device, the surrounding or environment in which the device is operated, or the owner of the device, are the primary tools for obtaining the needed information to make the determination. The operation of the mobile communication device is controlled by software in response to the detected information and therefore the sensors act as the “eyes and ears” of the device. An important element of such an intelligent sensor system is the ability to detect light. Generally, photodiodes, photodetectors, photodiode/detector sensors and senor arrays and the like are often used in light detection. These sensors and sensor arrays are typically based on silicon (Si) processing and silicon technology and are not integrated into the mobile communication device but rather are discrete elements.

Therefore, there is a need for intelligent, context sensitive, sensor systems and related devices for use in a mobile communication device to provide applications and features that are more sophisticated than those currently available. These advanced types of applications/features are expected to significantly improve the usability of mobile communication devices and to add value to the device and service providers.

It is desirable to use organic photodiodes/photodetectors in sensors and sensor arrays because they exhibit a flat response (efficiency) characteristic over a broad spectral range, and therefore are particularly well suited for use in detection in the visible and the ultraviolet (UV) spectral regions. The difference in performance between and organic and silicon photodetector is demonstrated by comparing the 0.3 A/W photosensitivity achieved for a polymer photodiode at the wavelength of 370 nm, to a typical 0.05 A/W for a UV-enhanced silicon photodiode at the same wavelength. Since the absorption region is very broad, they are also extremely well suited for detecting color images if combined together with suitable color filters.

Accordingly, the invention proposes simple and cost effective solutions for manufacturing various light detection systems, such as photodiodes/detectors, image scanners, and image capture devices using organic photodiodes. The invention further proposes substantial improvement to the manufacturing process, particularly if a large number of different sensor applications are realized with the same organic semiconductor technology.

Accordingly, it is a general goal of the present invention to provide an intelligent sensor system for use in a mobile communication device.

It is a further goal of the present invention to provide an organic light sensor system that is easy to manufacture and produce.

It is also a goal of the present invention to provide an organic light sensor system in a mobile communication device for use in image capture.

### SUMMARY OF THE INVENTION

In accordance with one aspect of the invention, an organic light sensor for use in a mobile communication device is presented. The light sensor includes at least one organic photodiode/photodetector for detecting the presence of illumination having a predetermined wavelength and for generating a light detection signal in response thereto. Means are provided to couple the light detection signal to the mobile communication device. The organic photodiode/photodetector may be a stacked geometry structure or a planar geometry structure or a combination of both. The organic photodiode/photodetector is carried on a substrate which may take on various forms for example, the display window of the mobile communication device or the cover of the IR port of the mobile communication device. Preferably, the substrate is transparent for the desired wavelength detection. The substrate may also be a non-transparent surface of the mobile communication device. Possibly, apertures in the mobile communication device are substantially aligned with the substrate to exposure the organic photodiode/photodetector to light. Possibly, the substrate may also be the cover of the mobile communication device. Preferably, the coupling means is an organic circuit coupled between the organic photodiode/photodetector and electronic circuitry of the mobile communication device.

In accordance with another aspect of the invention, the organic photodiode/photodetector has a planar geometry construction. A first electrode made from a low work function conducting material and a second electrode made from a high work function material, are formed side-by-side on a substrate surface. An organic material is applied between the first and second electrodes. The electrodes may be of an arbitrary size and shape. The substrate may be of an arbitrary size and shape. Possibly, the substrate may be an arbitrary non-conducting substrate surface.

In accordance with a further aspect of the invention, an organic image scanner for use in a mobile communication device is presented. An organic photodiode/photodetector defines a pixel element in the scanner. The scanner includes an array made up of an “M”×“N” matrix of pixel elements. The pixel elements detect the presence or absence of illumination and generate a light detection signal in response to the detection which represents an image segment captured by the array. Possibly, “N” is a single column and “M” is an arbitrary number of rows to capture a one dimensional image segment. Preferably, a sequence of one dimensional image segments are captured to form a complete scanned image. Possibly, “N” is an arbitrary number of columns greater than one and “M” is an arbitrary number of rows greater than one. The “N” columns by “N” rows define a sensor matrix to capture a two dimensional image segment. Preferably, the organic photodiode/photodetector structure may be a stacked geometry or planar geometry structure. Preferably, each of the pixel elements in the array is an arbitrary size.

### BRIEF DESCRIPTION OF THE DRAWINGS

Other objects, features and advantages of the present invention will become readily apparent form the following written description of preferred embodiments taken together with the drawings wherein:

FIG. 1a is a schematic representation of typical energy levels shown separated as parallel bands for materials used in organic photodetectors/photodiodes.

FIG. 1b is a schematic representation of the energy levels of FIG. 1a shown in contact as tilted bands.

FIG. 2 is a schematic representation of one “pixel” corresponding to a photodiode/photodetector device embodying the stacked geometry structure of the present invention.

FIG. 3 is a top view schematic representation of a photodiode/photodetector device embodying the planar geometry structure of the present invention.

FIG. 4 is a side view schematic representation of the photodiode/photodetector planar geometry structure shown in FIG. 3.

FIG. 5a is a schematic representation of a mobile communication device showing a single photodiode/photodetector positioned on the inner side of the protective display window of the mobile communication device.

FIG. 5b is a schematic cross-sectional view along the line a-a in FIG. 5a showing the photodiode/photodetector positioned on the inner side of the protective display window of the mobile communication device.

FIG. 6 is a schematic representation of a one-dimensional N×M sensor array made up of a number of photodiode/photodetector devices embodying the present invention.

FIG. 7 is a schematic representation of a mechanical arrangement for detecting movement of the one-dimensional array of FIG. 6.

FIG. 8 is a schematic representation of an N×M sensor matrix made up of a number of photodiode/photodetector devices embodying the present invention.

FIG. 9 is a schematic representation of a lens arrangement utilizing the sensor matrix of FIG. 8 shown mounted and positioned in a mobile communication device for image capture.

FIG. 10 is an enlarged schematic representation of a sensor matrix showing the sensor matrix positioned in the optical path in such way that the pixels defined by the photodiode/photodetector embodying the invention will be very close to the image surface.

FIG. 11 is a schematic representation of a matrix of photodiodes/photodetectors and integrated organic light-emitting diodes (OLED's) of the sensor matrix.

FIGS. 12a-12f are schematic representations of a number of different views of a mobile communication device showing possible positions to locate and mount the sensor matrix and arrays embodying the present invention.

### DESCRIPTION OF PREFERRED EMBODIMENTS

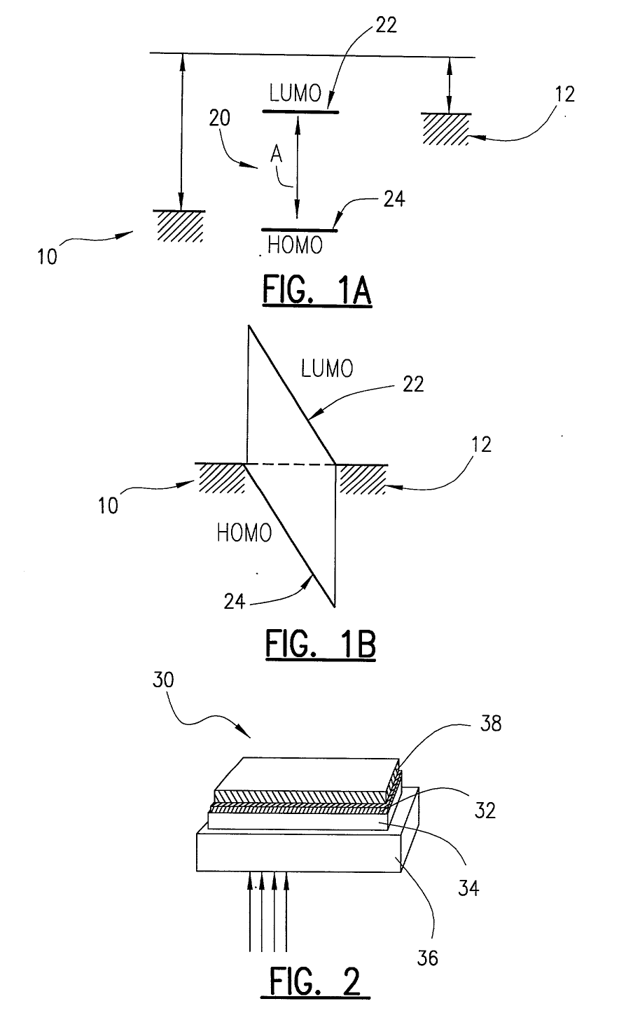

Turning now to the drawings and considering the invention in further detail, an explanation of the fundamental functional principle of operation of an organic sensor such as a photodiode/photodetector follows for a better understanding of the inventive concept. Considering FIGS. 1a and 1b, the operation of an organic sensor as contemplated in the present disclosure is based on the given organic material has a suitable absorption band (energy gap), and the use of two electrodes with different work functions. In FIG. 1a, the energy levels for a device with a single type of organic material and two dissimilar electrode materials is illustrated for the conditions when the “components” are not in contact with each other. One electrode generally designated 10 is a high work function conducting material typically, a transparent indium tin oxide (ITO) layer (or other transparent material), and another electrode generally designated 12 is a low work function conducting material typically, a metal such as Ca, Al, or a combination of several metals such as Mg and Ag or other inorganic materials. An organic material (or a blend) generally designated 20 has a suitable energy gap (A) between the Lowest Unoccupied Molecular Orbital (LUMO) 22, also referred to as the conduction band, and the Highest Occupied Molecular Orbital (HOMO) 24, also referred to as the valens band. The electrode materials 10, 12 are chosen such that the high- and low-work function materials' Fermi levels are as close in energy as possible to the HOMO 24 and LUMO 22 bands, respectively. When a single organic material device is manufactured, (that is, the structure is “joined” together), the “rule of equilibrium” will force the Fermi levels of the materials to the same level because charges will flow from the low work function material to the high work function material until their respective energy levels are substantially equal as illustrated in FIG. 1b. The flow of charges creates an internal electric field inside the device and which field is illustrated in FIG. 1b as a tilt of the HOMO band 24 and LUMO band 22, respectively. Due to the small number of free charge carriers in organic semiconductors, the electric field is often approximated to be evenly distributed through the whole material layer as represented by the straight tilted bands 24, 22 and very little band bending if any is expected to occur. A built-in electric field is created over the organic material due to the different work functions of the two electrode materials.

When a photon, with sufficient energy to excite an electron over the “band gap” (energy gap), is absorbed in the organic material, an optical excitation called an exciton is created in the organic material. The term exciton is also referred to as a bound electron-hole pair or a neutral bound state. Exciton types called singlets and triplets are formed. Optically generated excitons are always (radiative) singlet excitons. Both singlet and triplett excitons can be formed by “combining” opposite charges, also referred to as positive and negative polarons. De-excitation (or recombination) of the singlet occurs within a few nanoseconds of formation and leads to a photon emission known as fluorescence. Triplet exciton recombination is slower (about 1 millisecond to 1 second) and usually results in heat rather than light emission. The addition of a heavy metal atom in an otherwise organic molecule causes the characteristics of singlet and triplet exciton to mix speeding light emission to within about 100 milliseconds to 100 microseconds and this emission is referred to as phosphorescence. The dissociation of an exciton results in a free electron and a free hole that can be extracted due to the internal field, and thus detected. There are many factors affecting the creation of free electrons and holes but the internal field is considered to be the main contributor in this process. The created free charge carriers are detected as a voltage potential difference between the two dissimilar electrodes, or as a current in an external circuit.

In devices using a single organic material, it has been found that the charge separation process is not sufficiently effective and an improvement can be obtained by using a suitable electron accepting material with the organic material. An example of an electron accepting material is buckminsterfullerene C₆₀, used either in a separate layer or blended together with the organic semiconductor material, to achieve a significant improvement in the charge separation process. Organic semiconductor C₆₀ blends can be made as soluble derivatives of C₆₀ and can be synthesized.

An increased photosensitivity can also be achieved by increasing the electric field over the device, i.e. tilting the HOMO and LUMO bands even further by use of an external reverse voltage bias. Extremely high quantum yields of 50-80% electrons/photon have been achieved at 2 to 5 volts external reverse bias for some polymer photodiodes.

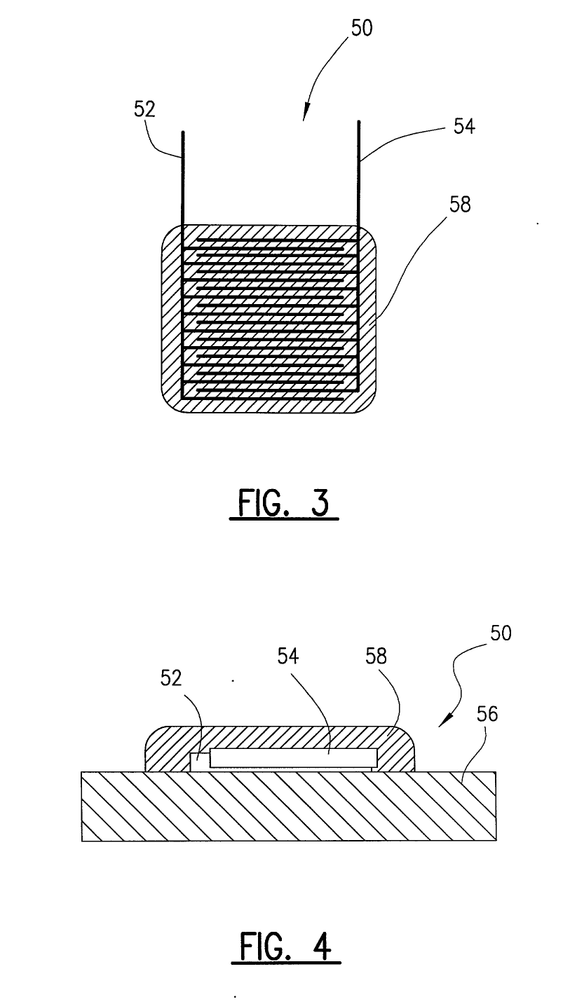

The manufacture of organic photodiode/photodetector devices is also easier than the manufacture of silicon photodiode/photodetector devices. A stacked configuration or stacked geometry structure of a photodiode/photodetector generally designated 30 embodying the present invention is shown schematically in FIG. 2. The layers of the photodiode/photodetector 30 are built-up one upon another with the organic semiconducting material (usually a conjugated polymer or a polymer blend) 32 sandwiched between two dissimilar electrodes. Usually the organic photodiode/detector 30 is manufactured by depositing the organic material 32 on a transparent electrode preferably ITO 34 carried on a transparent substrate 36. Various wet processes such as spin coating, printing, and the like now known or future developed can be used to deposit a polymeric material forming the organic photodiode/photodetector. Molecular material forming the photodiode/photodetector can be vacuum deposited. A top electrode 38 is evaporated on the organic material 32 and the photodiode/photodetector 30 is sealed, if required. Consequently, the manufacturing process is relatively simple and fast compared to silicon technology devices and very large areas can be covered to produce large area photodetectors.

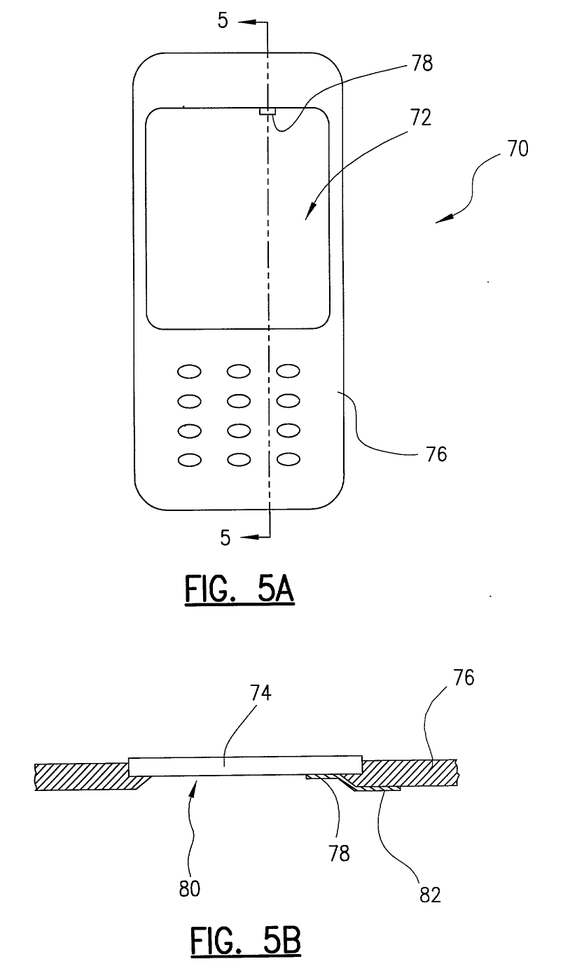

A planar geometry structure of a photodiode/photodetector generally designated 50 embodying the present invention is shown schematically in a top view in FIG. 3 and a side view in FIG.4. The planar geometry structure 50 is made with two electrodes 52, 54 formed side-by-side, in any shape, on any arbitrary non-conducting substrate surface. The manufacturing of a planar geometry structure differs from the stacked geometry structure because in the planar geometry both electrodes 52, 54 are first formed on the substrate 56 and the organic material 58 is simply applied between the electrodes. The electrode 52 is made from a low work function conducting material and the electrode 54 is made from a high work function material as discussed above. The application of the organic material can be of any suitable process, for example, printing from solution, by vacuum techniques for small molecular compounds and other methods now known or future developed. Since the two electrodes 52, 54 are deposited side-by-side, the selection of materials can be broader for example, no transparent material is needed. Furthermore, the substrate 56 does not have to be transparent since the structure can be illuminated from both directions. The planar configuration for a photodetector/photodiode sensor can thus offer a simpler manufacturing process.

The reader is referred to the literature in the art for additional information and explanation of examples of devices based on a single organic material, and examples of the wide range of different materials that can be used for this purpose, for example, conjugated polymer poly (3-octyl thiophene). U.S. Pat. No. 5,523,555 discloses single organic material devices.

A brief introduction to organic circuits and particularly to Organic Thin Film Transistors (OTFTs) follows to assist the reader in better understanding the disclosure of the invention. Since the printing technique is suitable for depositing conjugated polymers/molecules in the organic photodiode/photodetector structure embodying the invention, also referred to in the art as semiconducting polymers/molecules, it is desirable in some cases to also integrate the electronic circuitry with which the sensor operates as a part of the organic sensor or sensor system made up of several similar or different sensors. The integration of the electronic circuit to the organic sensor(s) can easily be accomplished if the electronic circuit is based on OTFTs.

The OTFTs have a Field Effect Transistor (FET) configuration, wherein the semiconducting material is an organic component and the Gate (G), Source (S), and Drain (D) terminals usually are made of various metals known to those skilled in the art. The OTFTs can be manufactured on flexible substrates for example, by vacuum deposition techniques at low temperatures. Currently, OTFTs with the best performance are manufactured by vacuum evaporation/sublimation techniques and are based on small organic molecules such as Pentacene and oligothiophenes, and metal “electrodes” (G, S, and D).

OTFTs can also be manufactured by various printing techniques such as, solution processing using printed “electrodes” as well. The performance of these printed OTFTs is not as good as vacuum deposited OTFTs however, performance is adequate for low frequency applications. In other words, if the printed organic circuits are used in low frequency applications, such as input detection from a sensor, which does not require a very fast detection signal, the performance should be good enough for most applications. Additionally, the benefits of the “printing” technique, such as the possibility to use a roll-to-roll process to obtain circuits on a flexible (or rigid) substrate, make OTFTs excellent candidates for simple, efficient and inexpensive mass manufacturing. Rather than first “printing” the sensors, the electrodes and the connection pads on the substrate (flexible or rigid) and then attaching the Si chip and connecting the pins, it is possible to manufacture all the electronic circuitry in the same process as the sensor itself, directly on the substrate by simple printing (or evaporation) techniques.

The invention also proposes that the sensor(s) circuit, or part of the sensor(s) circuit be implemented in some cases with organic circuits. An input/output (I/O) circuit, can be made by simply printing and/or vacuum depositing the entire electronic circuit on for example, the device cover substrate next to the sensor. The traditional electronic circuits/chips can be unproportionally expensive and difficult to integrate in such applications. An example of such an organic circuit could be an input/output (I/O) interface reading the input from the sensor(s) and forwarding the information regarding the “state” of the sensor(s) for example, to the central processing unit (CPU) controlling the operation of the device for further response and action. Thus, the printed circuit and the sensor(s) could form a “functioning” and “complete” unit of its own. The sensor(s) and the electronic circuit would thus form a “smart” system of its own and a simple data bus could be used between the sensor system and the main circuit of the device.

Turning now to FIGS. 5a and 5b, a schematic representation of a mobile communication device using an organic photodiode/photodetector embodying the present invention is illustrated therein and generally designated 70. The mobile communication device 70 includes a display window generally designated 72 for viewing graphics, alpha-numeric messages and other indicators displayed by the mobile communication device. The window 72 includes a transparent protective overlay 74 mounted in the cover or case 76 of the mobile communication device 70. An organic photodiode/photodetector sensor 78 embodying the present invention is located on the inner side 80 of the overlay 74. The sensor 78 is electrically coupled to electronic circuitry (not shown) of the mobile communication device 70 by a conductor generally designated 82 to carry signals to and from the sensor. The conductor may be of any suitable type known to those skilled in the art such as a printed circuit conductor, flat ribbon conductor, flexible printed circuit or any other type now known or future developed to carryout the intended function. The sensor 78 is used to detect the level or intensity of the external lighting and generates a light detection signal in response thereto which signal is coupled to the electronic circuitry of the mobile communication device. The external lighting may be visible, near visible or any other desired specific wavelength or spectral region that is to be detected. The information from the light detection signal may be used to control a number of functions of the mobile communication device such as turning the illumination of the display on or off or dimming the illumination, illuminating the keypad or causing a predetermined message to be displayed to determine other actions of the mobile communication device.

The structure of the organic photodiode/photodetector sensor 78 may be either the stacked geometry or planar geometry and may be manufactured directly on the inner side 80 of the protective overlay 74. For the stacked geometry structure, a high work function transparent electrode such as ITO, or other transparent inorganic conductor (e.g. ZnO), or a conducting polymer (e.g. PEDOT), is first deposited in the desired location on the inner side 80 of the protective overlay 74. The deposition can be a vacuum deposition technique or a solution processing technique as discussed above dependant upon the material used. The organic semiconductor material (including dopants or charge separating compounds) is then deposited by solution processing or vacuum techniques. The top electrode material (such as Al or other low work function material or material combination) is deposited on top of the organic material(s). The organic photodiode/photodetector device thus manufactured is optionally protected by proper sealing means if required.

For the planar geometry structure, the two different electrode materials are first deposited side-by-side in the desired location on the inner side 80 of the protective overlay 74. The electrode materials may be the same as used in manufacturing the stacked geometry structure as described above. The requirement is simply that the electrodes are made of a low and a high work function material, respectively. The electrodes can be deposited by vacuum techniques, various wet processing techniques as described above, or using other techniques now known or future developed.

Although the sensor 78 is described above as being located on the inner side 80 of the protective overlay 74 which serves as the substrate, the invention contemplates the use of any other “transparent” substrate or part in the mobile communication device as the substrate for the planar or stacked geometry structure. For example, the substrate can be the transparent cover over the LED and photodetector in the IR-port, or any other “transparent” substrate or part in the device. As used in this disclosure, the term “transparent” means in general that the substrate is “transparent” to the wavelength one wishes to detect in addition to its normal accepted definition as used in the visual context

The substrate may be located on the exterior of the mobile communication device case or cover. Preferably, the substrate is located on the interior of the communication device case. The substrate can be arranged and aligned for example so that the external light can be detected through holes, apertures, slots and the like in the cover. In this arrangement, the organic photodiode/photodetector comprising the sensor can be manufactured directly on the PWB carrying the electronic and electromechanical components of the mobile communication device to simplify the connection to the electronic circuit for example the CPU. The sensor can also be placed in such a way that the protective overlay serves as the “window” for the sensor.

If the organic material(s) of the photodiode/photodetector is deposited by a wet/vacuum process on the device covers or other substrate as described above, the manufacturing process can be extended to simultaneously manufacture the OTFT based electronic circuitry required. The data from one or several sensors, not necessarily all light detectors, can be combined to forward the data to the main electronic circuitry or CPU in a suitable form. If the sensor(s) are positioned on a substrate separate from the CPU and other electronic circuits for example, on the device cover, it would be beneficial to manufacture an organic circuit next to the sensor or preferably the sensor system with several sensors and/or other functional components. The data from the sensor(s) could thus be forwarded from the organic circuit to the main electronic circuit by a simple serial data bus carrying ground and voltage potentials, clock and data signals. The number of connectors between the main circuit and CPU and the functional cover or other separate part of the device could then be minimized if the substrate has several functional components or sensors added to it. Connection of the sensor to the circuit can be done in any suitable way. Preferably, several such sensors or different types of sensors can be connected to an organic circuit on the same substrate, and then connecting the organic circuit to the main circuit (not illustrated).

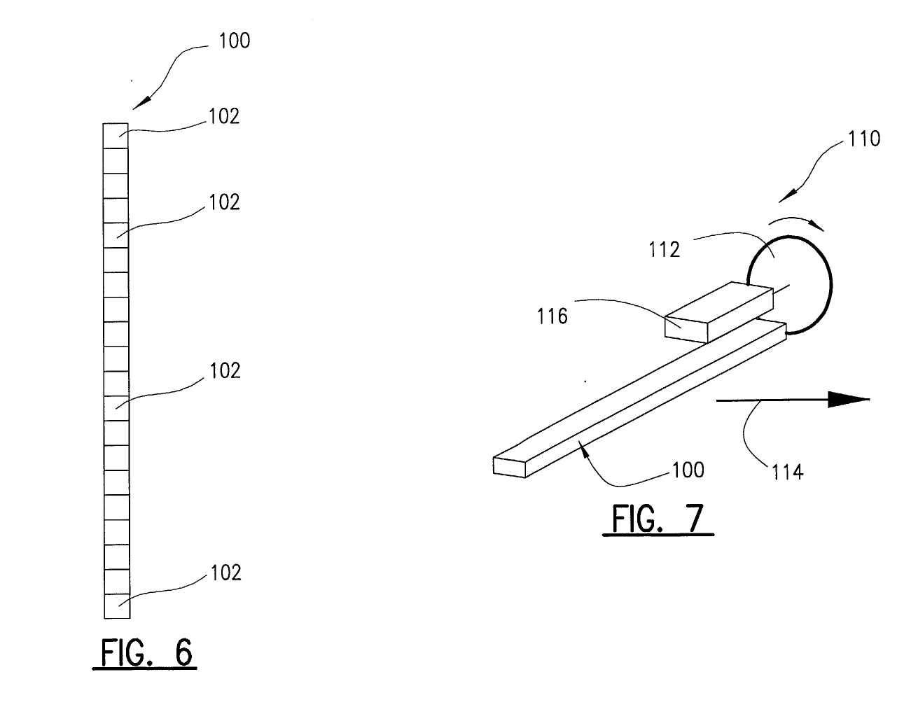

In a further embodiment, the organic photodiode/photodetector of the present invention defines a “pixel element” that may also be used and manufactured as a sensor array or as an image scanner in the mobile communication device. The array can have an arbitrary pixel size and length. FIG. 6 illustrates “one dimensional” (1-D) array generally designated 100 which is made up of an array of a single column of pixel elements 102, 102 to detect images when moved perpendicular to the array direction along the surface. The sensor array can be used to scan text or images carried on a “smooth” surface. The pixel elements of the array are coupled to the electronic circuitry in the mobile communication device to forward the scanned data for storage or processing. The scanned data may be displayed on the communication device screen or may be captured and forwarded wirelessly to a remote receiving site. The organic photodiode/photodetector of the array may be of an arbitrary pixel size depending on the application, and may be either of the stacked or planar geometry structure described above.

A schematic representation of a mechanical arrangement for detecting movement of the one-dimensional array shown in FIG. 6 is illustrated in FIG. 7 and is generally designated 110. The pixel array 100 is coupled to a mechanical wheel 112 to detect the perpendicular movement of the array in the direction indicated by the arrow 114 along a surface which carries an image (not shown) to be scanned. A rotation detector 116 carried by the wheel 112 combines the data of the movement and the “images” from the individual detectors of the array as the array moves relative to the surface to produce a two dimensional image as the wheel rotates.

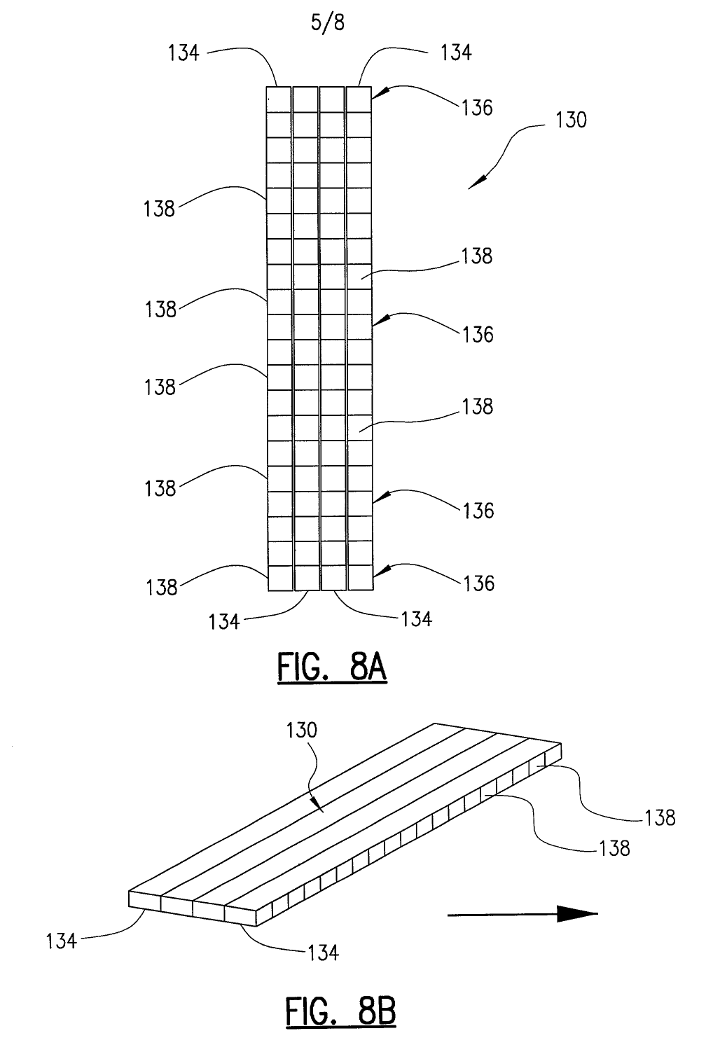

In a further embodiment, the organic photodiode/photodetector of the present invention defining a pixel element can be used and manufactured as a “two dimensional” (2-D) “N”×“M” sensor matrix designated generally 130 in FIG. 8. The sensor matrix 130 is made up of an array of columns 134, 134 of any number of rows 136, 136 defining an arbitrary length with more than one pixel element 138 in each row 136. The sensor matrix 130 moves along the surface to detect images (not shown) carried on the surface. The pixel elements 138 of the sensor array 130 are coupled to the electronic circuitry in the mobile communication device similarly to the one dimensional array discussed above in connection with FIG. 6. The sensor matrix 130 may be carried directly by the mobile communication device to scan an image by moving the device itself over the surface to capture the image. The sensor matrix 130 may also be combined with a mechanical arrangement as discussed above in connection with FIG. 7 to detect the perpendicular movement of the sensor matrix. The movement and speed of movement can also be determined by tracking how the scanned 2-D image data shifts in the 2-D pixel element array forming the sensor matrix 130. The CPU of the mobile communication device operates software designed for this purpose to combine “small segments” of the image to form a complete image.

In a further embodiment, the number of pixel elements in the “N”×“M” sensor matrix can be increased to approximate a “digital camera” sensor. The pixel elements are coupled to electronic circuitry in the mobile communication device in a similar manner as discussed in connection with the arrays of FIG. 7 and FIG. 8. The CPU of the mobile communication device operates software designed to trace the movement of the image within the pixel element matrix to combine smaller 2-D segments of the image to form a complete image. Appropriate clocking and sampling signals are generated in the electronic circuitry of the mobile communication device to capture a sequence of images at a predetermined sampling rate. The captured sequence of images are stored in a storage medium such as a large scale RAM device for subsequent retrieval to display a “still” captured image or a sequence of moving images in a playback mode. The images thus retrieved are shown in the display of the mobile communication device. Optionally, the mobile communication device may also be equipped with sound capture and playback functionality to capture, record and playback sound in synchronization with the image playback. A suitable color filter for each pixel can be used to scan multi-color or full color images with the mobile communication device.

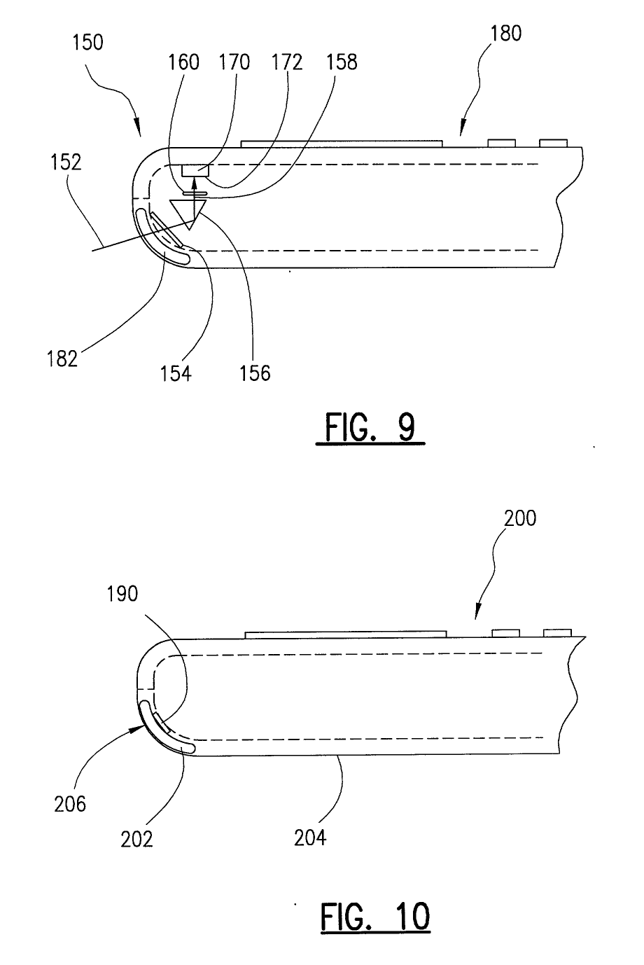

Turning now to FIG. 9, a schematic representation of a lens arrangement generally designated 150 utilizing the sensor matrix discussed in connection with FIG. 8 above is shown mounted in a mobile communication device generally designated 180 in FIG. 9. The sensor matrix detects the external light reflected by the image. The lens arrangement 150 receives light reflected from a desired image along an optical image path 152. The optical path 152 may pass through an optical element such as a lens or lens system 154 to an optical means such as the prism shown generally as 156. The prism 156 bends the optical path 158 to direct it through another lens or lens system 160 to focus it at the surface 172 of the sensor matrix 170 embodying the present invention. The lens arrangement 150 is positioned in the mobile communication device 180 in such way that a suitable focal distance between the matrix sensor and the image to be scanned is obtained. The image is illuminated by external lighting only and it is the reflected light that is detected by the matrix sensor 170.

In a further embodiment of the invention illustrated in FIG. 10, a sensor pixel matrix generally designated 190 is shown mounted in a mobile communication device generally designated 200 in a fixed location behind a window 202 mounted in the case or cover 204. In this embodiment, the sensor pixel matrix 190 of the device 200 is located as close as possible to the image to be scanned. As shown in FIG. 10, the window 202 of the mobile communication device 200 is located such that the surface 206 of the window 202 is substantially in contact with the surface carrying the image when the device is used for scanning. In contrast to the embodiment of FIG. 9 wherein external light illuminates the image, in the embodiment of FIG. 10, the image is illuminated by internal light sources located close to the pixel elements of the sensor matrix 190 as described and shown in further detail below in connection with FIG. 11. Additionally, the embodiment of FIG. 10 does not require complex optical means to focus the image on the matrix sensor.

A schematic representation of the sensor pixel matrix 190 embodying the invention is illustrated in FIG. 11. The sensor pixel matrix 190 is a combination of organic photodetectors and organic light emitting diodes (OLED) and is based on the similarity between the photodetector structure described above and the organic light-emitting diode structure to provide a combined illumination-detection system. In this case, the OLEDs have substantially an identical structure to the organic photodetector/photodiode as described above (i.e. ITO, organic semiconductor, and metal electrode). In practice, as is known to those skilled in the art, the organic materials used in OLEDs may be slightly different than the organic material used in the organic photodiode/photodetector. In principle, an organic photodetector can be used as an OLED, and vice versa. The structures and materials are varied only to optimize for different purposes. Preferably, a combination of organic photodetectors and OLEDs are manufactured as a matrix wherein the OLEDs are integrated into the matrix, at suitable positions, for obtaining the desired illumination of the scanned image. As illustrated in FIG. 11, the sensor pixel matrix 190 is an “M”×“N” matrix. The pixel matrix 190 is made up of an array of columns 192, 192 of any number of rows 194, 194 defining an arbitrary length with more than one pixel element 196, 196 in each row 194. The pixel elements 196 may include OLEDs 198, 198 located at a number of positions in the matrix in a suitable ratio to the photodetector pixel elements to provide a desired illumination. The organic photodiodes and OLEDs can be of a stacked or planar structure or a combination of stacked and planar structures.

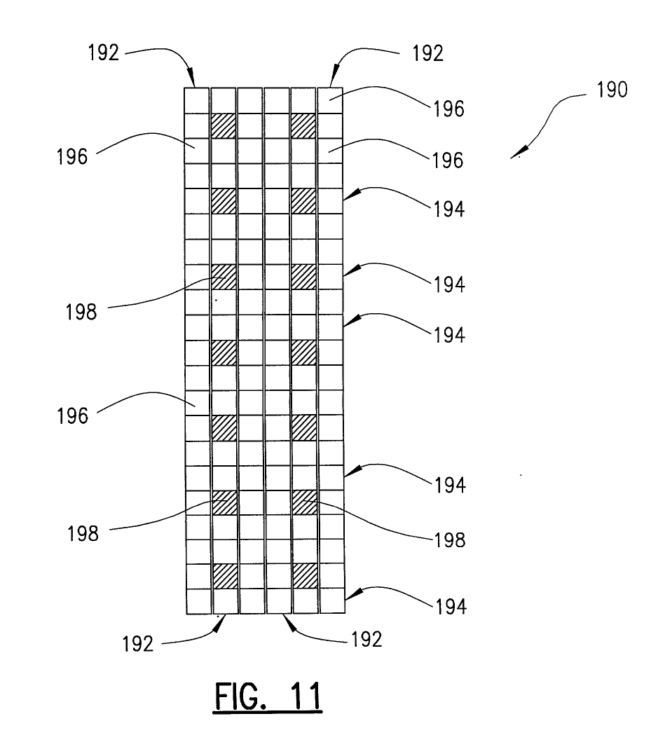

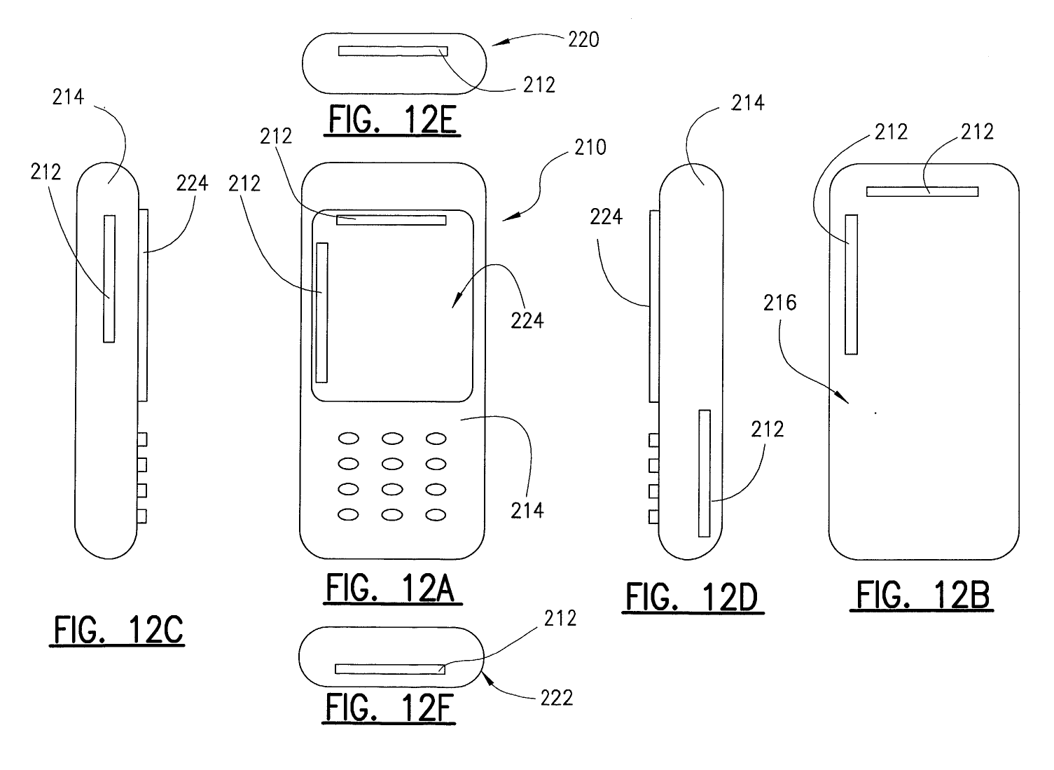

Turning now to FIGS. 12a to 12f, the sensor matrix and arrays embodying the present invention are shown schematically as they might be located and mounted in a mobile communication device generally designated 210. The arrays 212 can be manufactured as a separate substrate and inserted into the side of the cover 214 of the device as shown in FIGS. 12c and 12d. FIG. 12b shows the array 212 mounted in the rear cover 216 of the device 210. FIGS. 12e and 12f show the array 212 mounted in the top 218 and bottom 222, respectively of the device 210. The sensor array 212 can be manufactured directly at various positions on a window protective overlay 224 on the cover 214 or as a separate window cover. Preferably, the sensor array is on the inner side of the window. When the sensor array is mounted on the window 224, light reflected from the image from existing external lighting, light from integrated light sources or light emitted from display illumination provide the necessary light to the sensor array.

The sensor matrix and arrays embodying the invention can be integrated onto printed wiring boards (PWB) or other substrates within the mobile communication device and an optical arrangement or means guides the image to the sensor matrix. In this case, electrical connection of the pixel elements to the electronic circuitry of the mobile communication device is simplified.

Organic light sensors and their related manufacture for use in mobile communication devices have been described above in several preferred embodiments. Numerous changes and modifications made be made by those skilled in the art without departing from the spirit and scope of the invention and therefore the present invention has been described by way of illustration rather than limitation.

The invention claimed:

1. An organic light sensor for use in a mobile communication device, comprising:
at least one organic photodiode/photodetector for detecting the presence of illumination having a predetermined wavelength and for generating a light detection signal in response thereto, and
means for coupling said light detection signal to said mobile communication device.

2. The organic light sensor as defined in claim 1 wherein said one organic photodiode/photodetector further comprises a stacked geometry structure.

3. The organic light sensor as defined in claim 1 wherein said one organic photodiode/photodetector further comprises a planar geometry structure.

4. The organic light sensor as defined in claim 1 further comprising said one organic photodiode/photodetector is carried on a substrate.

5. The organic light sensor as defined in claim 4 wherein said substrate further comprises the display window of the mobile communication device.

6. The organic light sensor as defined in claim 4 wherein said substrate further comprises the cover of the IR port of the mobile communication device.

7. The organic light sensor as defined in claim 4 wherein said substrate is transparent for the desired wavelength detection.

8. The organic light sensor as defined in claim 4 wherein said substrate further comprises a non-transparent surface of the mobile communication device.

9. The organic light sensor as defined in claim 8 wherein apertures in the mobile communication device are substantially aligned with said substrate for exposure to light.

10. The organic light sensor as defined in claim 8 wherein said substrate further comprises the cover of the mobile communication device.

11. The organic light sensor as defined in claim 1 wherein said coupling means further comprises an organic circuit coupled between said at least one organic photodiode/photodetector and electronic circuitry of the mobile communication device.

12. A planar geometry structure organic photodiode/photodetector, comprising:
a substrate having at least one surface;
a first electrode made from a low work function conducting material;
a second electrode made fro a high work function conducting material;
said first and second electrodes formed and positioned side-by-side on said substrate surface, and
an organic material applied between said first and second electrodes.

13. The planar geometry photodiode/photodetector defined in claim 12 wherein said first and second electrodes are of an arbitrary size and shape.

14. The planar geometry photodiode/photodetector defined in claim 13 wherein said substrate is of an arbitrary size and shape.

15. The planar geometry photodiode/photodetector defined in claim 14. wherein said substrate further comprises an arbitrary non-conducting substrate surface.

16. An organic image scanner for use in a mobile communication device, said scanner comprising:
an organic photodiode/photodetector defining a pixel element;
an array made up of an “N” column×“M” row matrix of pixel elements for detecting the presence or absence of illumination and generating a light detection signal in response thereto representative of an image segment captured by said array.

17. The organic image scanner as defined in claim 16. wherein “N” is a single column and “M” is an arbitrary number of rows to capture a one dimensional image segment.

18. The organic image scanner as defined in claim 17 wherein a sequence of one dimensional images segments are captured to form a complete scanned image.

19. The organic image scanner as defined in claim 16 wherein “N” is an arbitrary number of columns greater than one and “M” is an arbitrary number of rows greater than one and defining a sensor matrix to capture a two dimensional image segment.

20. The organic image scanner as defined in claim 16 wherein said organic photodiode/photodetector farther comprises a stacked geometry structure.

21. The organic image scanner as defined in claim 16 wherein said organic photodiode/photodetector further comprises a planar geometry structure.

22. The organic image scanner as defined in claim 16 wherein each of said pixel elements in said array is of an arbitrary size.
